(19) United States
(12) Patent Application Publication
(10) Pub. No.: US 2015/0253556 A1
(43) Pub. Date: Sep. 10, 2015

(54) Confocal Incident-Light Scanning Microsope For Multipoint Scanning

(71) Applicant: CARL ZEISS MICROSCOPY GMBH, Jena (DE)

(72) Inventors: Daniel Schwedt, Weimar (DE); Tiemo Anhut, Jena (DE); Tobias Kaufhold, Jena (DE)

(21) Appl. No.: 14/432,182

(22) PCT Filed: Sep. 27, 2013
(86) PCT No.: PCT/EP2013/070206

§ 371 Date: Mar. 27, 2015

(30) Foreign Application Priority Data
Sep. 28, 2012 (DE) 10 2012 019 464.1

(51) Int. Cl. G02B 21/00; H01J 37/28

(52) U.S. Cl. CPC G02B 21/0032; H01J 37/28

(57) ABSTRACT

Confocal multipoint scanning microscopes (1) comprising a multi-beam light source (2), confocal detectors (10) a beam splitter (4) for coupling the illuminating beam path (B) and the detecting beam path (D) into a common beam path (C), and an adjustable deflection unit (5) and a microscope lens (8) have the disadvantage that the properties of the image field cannot be modified in the same way as for a single-point scanning microscope by appropriate activation of the deflection unit, without the relative position of the points changing in relation to one another. The invention proposes solving this problem by having a means (7) for the manipulation of a spatial position of the partial beams or for the manipulation of a phase position of the partial beams relative to one another arranged in the common beam (C) between the main beam splitter (4) and the deflection unit (5). In this way, it is possible to vary image field characteristics without changing the relative position of the points in relation to one another. Confocal microscopy.

The invention concerns a confocal scanning microscope, having an illumination beam path with a confocal multibeam light source, a detection beam path with confocal detectors, a beam splitter which couples the illumination beam path and the detection beam path into a joint beam path, an adjustable deflection unit in the joint beam path and a microscope objective for focusing the partial beams of the multibeam light source in a specimen plane, likewise in the joint beam path. Advisedly, such microscopes also comprise a scan optics and a tube lens between the deflection unit and the microscope objective.

According to the invention, a detector is confocal when it, or a diaphragm connected in front of it, is arranged in (or in proximity to) a confocal plane. Confocal means here that a diaphragm for limiting the light uptake to a small “target volume” at the site of the specimen is arranged in a plane of the detection beam path which is optically conjugated to the focal plane of the objective at the specimen end. The same holds for a confocal multibeam light source.

A multibeam light source is a means in which light a) is emitted simultaneously or at least in time-staggered manner in spatially separate regions of a spatial plane, or b) it emerges from several orifices or optical elements such as lenses or beam splitters. In any case, these regions of light emission or light emergence which define the resulting illumination spots in the specimen are relatively fixed in position relative to each other. However, the orifices can be (continuously or discretely) variable in size, although this does not change their relative position to each other.

Light in the sense of the invention is any radiation which can be manipulated by optical means, especially also ultraviolet (UV) and infrared (IR) radiation. Typically, one or more lasers are used as the light source. The microscope is then called a “multifocal laser scanning microscope”. Instead of one or more lasers, nonlaser sources, such as light-emitting diodes (LEDs), can also be arranged accordingly.

Typically, the deflection unit comprises two deflection mirrors (galvanometer mirrors), which can move about axes orthogonal to each other. The deflection unit thus enables a scanning of the sample along a grid by tilting the joint beam path, which results in a simultaneous parallel displacement of the illuminated target volumes (“spot pattern”) on the specimen, while specimen light from each of the simultaneously illuminated specimen locations is picked up by means of the detectors arranged in the detection beam path. The deflection unit can also comprise only one movable minor, which can move about only one or two axes, as in US 2007/127003 A1.

The region of the specimen scanned by means of the deflection unit during a scanning process is known as the scanning field, while the region scanned by an individual one of the multiple spots is known as a respective grid field. Since an image can be assembled from the detection values picked up in the scanning field, it is also known as an image field.

The known multiple-spot scanning microscopes have the drawback that the properties of the image field cannot be modified in the same way by corresponding control of the deflection unit as in a single-spot scanning microscope. Thus, for example, the image field in a single-spot scanning microscope can be rotated by different relative adjustment of the scanning speeds along the scanning axes, i.e., different rotational speeds of the deflection minor. In a multiple-spot scanning microscope, however, a change in the relative scanning speeds leads to a change in the relative position of the spots among each other, especially different distances from neighboring spots. Furthermore, the fixed distances of the spots in the specimen plane establish the minimum image field size which can be scanned multifocally, whereas with a single-spot scanning microscope it is variable thanks to different adjustment of the deflection width (amplitude) of the deflection mirror.

For influencing of the scanning direction in a single-spot scanning microscope, JP 8334698 A describes, for example, arranging a Dove prism in the joint beam path between the deflection unit and the objective. Furthermore, it is known from US 2006/012875 A1 how to arrange an Abbe-Konig prism in a pupil of the joint beam path between main beam splitter and specimen in a confocal scanning microscope with linear illumination and detection, for rotation of the image field. In this way, in particular, a selected region (“region of interest”, ROI) can be rotated. The rotation is again canceled by the same prism during the detection of the specimen light.

The invention solves the problem of improving microscopes of the kind mentioned above so that at least one image field property can be variably adjusted.

The problem is solved by a microscope having the features indicated in claim 1 or 11.

Advantageous embodiments of the invention are indicated in the subclaims.

For example, the multibeam light source can be a multiaperture plate which is relatively stationary to the main beam splitter, as in U.S. Pat. No. 6,028,306, with a single light source connected in front of it, which simultaneously illuminates several (or all of) the openings (apertures) of the plate. The disclosure content of U.S. Pat. No. 6,028,306 regarding the configuration of scanning microscopes with stationary multibeam light source is incorporated here in its full extent. Furthermore, it is also possible to illuminate by said light source an array of microlenses, such as is shown by Bewersdorf et al. in “Handbook of Biological Confocal Microscopy” (James B. Pawley), third edition, p. 550 (2006). Alternatively to a multiaperture plate or a microlens array, the multibeam light source can be, for example, an array of spaced-apart light sources, such as spatially separated laser diodes or VCSEL. Moreover, it is also possible to produce a plurality of beams of approximately equal intensity from a single laser light source coupled into the system by beam splitting mechanisms, as in U.S. Pat. No. 6,219,179 B1. The multibeam light source can be connected after a collimation optics.

The confocal multibeam light source is imaged by the objective onto the specimen. The light source here typically serves for the (multifocal) excitation of fluorescence of a fluorescent dye contained in the specimen in the illuminated spots, which thereupon emit fluorescent light which is imaged by the objective on the detectors coordinated with the spots. The light conducted along the illumination beam path to the specimen is known as illumination light, and the light reflected, scattered and emitted by the specimen is called specimen light. If the multibeam light source produces N x M spots illuminated by the objective on the specimen, at least N x M separate confocal detectors are required. For example, an identical multiaperture plate as in the multibeam light source can be arranged for this purpose in the detection beam path, and a detector behind each of the apertures.

According to the invention, the solution for the problem is that means for manipulation of a spatial position of the partial beams are arranged in the joint beam path between the main beam splitter and the deflection unit. In this way, image field properties can advantageously be variably configured.

According to a first, especially preferred embodiment, the means for manipulation of the spatial position of the partial beams determine the relative position of the partial beams to each other, in particular, laterally to the optical axis of the partial beams, while the relative distances of the resulting light spots from each other in one (all) image plane(s) remain intact. For example, the partial beams can be tilted relative to each other (relative angle change) by the means for manipulation and/or the distances of the partial beams from each other can be changed. In this way, a variable image field rotation is possible in combination with accordingly adapted control data for the scanning unit.

In a first advantageous variant embodiment, the means for manipulation of the spatial position of the partial beams comprise an adjustable image field rotating element, especially a pivoting Abbe-Konig prism or a Dove prism or a Schmidt-Pechan prism or a K mirror. In this way, the image field in a multiple-spot scanning microscope can be rotated by a variable orientation of the partial beams.

This is especially advantageous, for example, when rapid processes are being investigated in elongated regions of the specimen. If these elongated regions lie along the line scanning direction (higher scanning rate than in the column scanning direction), the image format can be varied in favor of an increased frame rate, for example, by a reduction in the number of lines. For this purpose, the line scanning direction can be adapted to the orientation of the elongated region by a rotation of the spot pattern according to the invention, so that the long dimension of the elongated region is oriented in the direction of the line scanning. An adapted number of lines for scanning is then determined by means of the short dimension of the elongated region. In this way, rectangular images are scanned whose number of lines is less than their number of columns. Thus, the time expense in obtaining the information is less than that of a nonrotated scanning field, thanks to the reduced number of lines.

Furthermore, an image field rotation can be advantageous when high speeds of movement are being studied for directed vesicle movements under large zoom. In this case, each individual illumination spot overlaps a large number of scanning lines before the partial images of the individual spots touch each other, with a hard jump in the imaging time between the end of one partial image and the contact with the following one. In the prior art, this can produce imaging artifacts on account of rapid movements. For example, the same vesicle may be visible twice in the image. Such artifacts can be reduced according to the invention by placing the direction of the line scanning in a predetermined main direction of movement of the particular specimen components.

Another advantageous aspect of the optical image field rotation in a multiple-spot scanning microscope is that the spot pattern (in connection with an adapting of the rotational speeds of the scanner by means of appropriate control data for the deflection unit) can also be oriented so that the scanning of the specimen occurs along a line connecting two spots. In this way, the same line can be photographed with a line scanning up to N times (or M times). In particular, for the case M=1 (series of spots extending in one dimension), it can be advantageous to rotate the image field so that the direction of extension of the series of spots in the object field is orthogonal to its direction of extension in a plane of a confocal diaphragm. In this case, the time difference between the data recording of immediately neighboring light spots (n and n+1) at the same location of the specimen is minimal. For M>1, the spot pattern can be rotated so that the dimension with the larger number of spots lies in the direction of the scanning lines. This can be used with advantage, for example, for high-resolution microscopy evaluations such as SOFI (Dertinger et al.: “Fast, background-free, 3D super-resolution optical fluctuation imaging (SOFI)” in Proc. Nat. Acad. Sci. USA (2009) 106(52):22287-22292), since in this case few movement artifacts occur between the different lines. Such artifacts, which are unavoidable in the prior art, have negative impact on the high-resolution images, since they enter into the correlations which form the foundation of these methods.

Advisedly, a microscope according to the invention can therefore comprise a control unit, which controls the deflection unit in dependence on an adjustment of the image field rotating element.

In a second advantageous variant embodiment, which can be combined with the first one, the means for manipulation of the spatial position of the partial beams comprise a variable zoom optics. This enables a variable adaptation of the scannable size of the image field by modification of the relative spot distances from each other in the specimen. A changing of the spot distances relative to each other advantageously enables a variability of the minimum image field and furthermore a greater reduction in scanning field size, which can be accomplished for example by means of the method proposed in U.S. Pat. No. 7,385,165 or by “stitching” methods which differ from this.

It should be noted that a significant pupil underfilling is avoided, since this will reduce the resolution of the microscope. Advisedly, however, a (slight) underfilling of the pupil means that a pupil resting on or between the deflection minors is imaged at reduced size in the objective pupil, which increases the relative angles of the partial beams to each other. This, in turn, means that the minimum image field is enlarged by a pupil underfilling (zoom out). Conversely, a zoom in is equally possible by an enlargement of the deflection mirror pupil in the objective pupil. Boundary conditions on the degree of over and underfilling of the objective pupil are framed in terms of light losses, resolution and contrast. An overfilling of the objective pupil on the one hand produces a loss of illumination strength, and on the other hand the hard stop down of the excitation light at the pupil edge intensifies the Airy rings. An underfilling of the pupil, as already mentioned, causes resolution losses due to a broadening of the PSF and moreover carries the risk of fluorescence losses at aperture boundaries in the system, since the objective pupil is imaged at increased size on/between the deflection minors and the objective pupil is entirely filled by the fluorescence. Therefore, preferably the under or overfilling is such that the loss of illumination intensity is at most 50%.

In a third advantageous variant embodiment, which can also be combined with the first and/or the second one, the means for manipulation of the spatial position of the partial beams comprise a telescope optics for generating an intermediate image and an array of reflection elements which are continuously adjustable in their direction of reflection. In this way, the resulting spot positions in the object plane can be modified with respect to each other, without influencing the point-spread function.

Preferably, in this embodiment, a principal plane of an exit optics of the telescope optics lies outside the telescope, especially in the array of reflection elements, especially such that all telescopically imaged partial beams are imaged on different reflection elements. This enables an individual manipulation of partial beams with high accuracy.

According to a second preferred embodiment, the means for manipulation of the spatial position of the partial beams determine the relative position of the partial beams to a predetermined point on an axial beam, especially on an axial beam in the means. In this way, the imaging in the specimen can be optimally adjusted.

Preferably the means for manipulation of the spatial position of the partial beams in this embodiment comprise a movably mounted, transparent, plane parallel plate. In this way, the partial beams can be shifted laterally, for example, in order to adjust an optimal pupil filling.

According to a second aspect of the invention, it is proposed that the joint beam path between the main beam splitter and the deflection unit comprises means for manipulation of a phase position of the partial beams relative to each other. This makes it possible to manipulate image field properties in a confocal microscope which transmits only a limited image field due to multiple beam paths. Thanks to such means, one can create for example path differences between the partial beams, for the purpose of wave front formation, a defocusing, or for correction of aberrations (such as those which are objective-dependent), especially spherical errors.

Preferably the means for manipulation of a phase position of the partial beams comprise a spatial light modulator. This enables the manipulation of the relative phases of the partial beams with high accuracy.

It is also advantageous for the means of manipulation of a phase position of the partial beams to comprise a membrane mirror. A membrane mirror can change the phase fronts of the partial beams and thus correct for imaging errors of various order (such as sphere, coma, astigmatism). In addition, the focus position in the object plane can be varied by means of a membrane minor within certain limits. For example, one can optimize the adjustment of the minor surface in confocal scanning microscopes by means of the resulting image brightness.

Advantageously, in all embodiments and variant configurations the means of manipulation are arranged (at least approximately) in a pupil plane (lying between the main beam splitter and the deflection unit) or at least in proximity to it. In this way, the beam geometry on the way to the objective, initially firmly established by the multibeam light source, can be modified without the manipulation affecting the entire scanning field. Furthermore, due to the reversibility of the light path in the joint beam path, manipulations of the spatial position of the partial beams are also reversed once again for the specimen light, so that the imaging on the confocal diaphragm arrangements remains invariant in the illumination and detection beam path.

Preferably, the joint beam path comprises optics for this purpose to create the (supplemental) pupil plane.

The invention also includes embodiments in which the microscope objective images several spots from a real or virtual image plane of the multibeam light source in the specimen plane.

The invention in particular makes easier panning and the rapid selection of predetermined ROI by corresponding control of the deflection unit.

The invention is explained more closely below by means of sample embodiments.

In the drawings are shown:

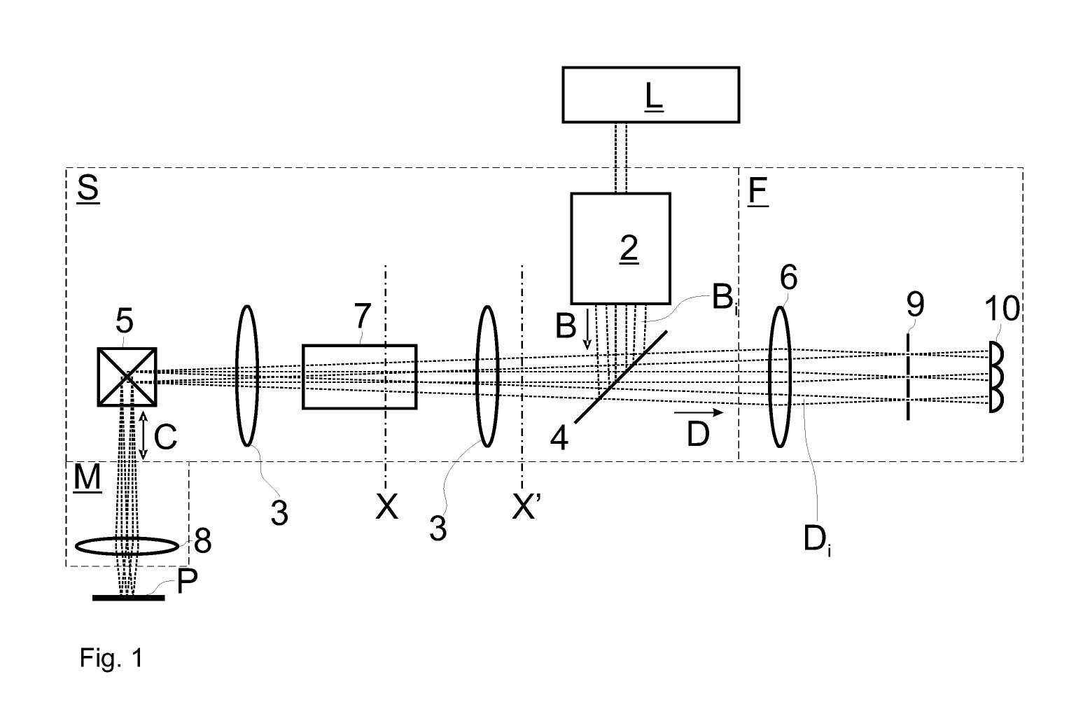

FIG. 1 a front-illumination scanning microscope with a multibeam light source.

FIG. 1 shows a multifocal LSM 1 with a multibeam light source 2, coupled in by a laser L. The laser L is removably connected to the scanning module S of the microscope 1, for example across lightguides at coupling points, so that it is coupled into the illumination beam path B and creates at the multibeam light source 2 a number N×M of partial beams Bᵢ (of approximately the same intensity, three being shown as an example), having a fixed spatial angle relation to each other at the exit of the multibeam light source 2. In the joint beam path C, furthermore, there are arranged optics 3 which create a supplemental pupil plane X between the main beam splitter 4 and the deflection unit 5 (with one or two deflection minors, not shown) (can be eliminated in other embodiments, especially for other kinds of manipulation of the partial beams). The main beam splitter 4 is, for example, a dichroic spectrally separating beam splitter and it couples the illumination light into the joint beam path C so that the excitation light goes toward the specimen across the deflection unit 5. In the pupil plane X, a means 7 is arranged for the (“descanned”) manipulation of a spatial position of the partial beams Bᵢ. The joint beam path C furthermore has a scanning optics (not shown) and a microscope objective 8 for imaging several spots from an image plane of the multibeam light source 2 in a specimen plane P. The detection beam path D, coupled by the main beam splitter 4 with the illumination beam path B, contains a multiaperture plate in the detection module F as confocal detection diaphragms 9 coordinated with the illumination spots, with a detector 10 arranged behind each diaphragm aperture.

Since the N×M pinhole diaphragms of the multiaperture plate are firmly coordinated with each other in a plane, they are all confocally imaged in the specimen P. The pinhole diaphragms here are adjustable in size, for example; in other embodiments (not shown), they can have a (uniform) fixed size or different fixed sizes. The size of the pinhole diaphragms dictates the geometry of the partial beam paths Bᵢ, Dᵢ. This holds equally for excitation and detection beams, since these run coaxially in opposite directions in the joint beam path C.

The means 7 for manipulation of the position of the partial beams can be, for example, an image field rotating prism, a zoom optics, a telescope with connected switchable mirror array or a sequential combination of these elements or a subset of same. In one preferred embodiment, the means 7 contain a sequential arrangement of all four mentioned elements, the zoom optics being located closest to the deflection unit, followed by the image field rotating prism, after which comes the telescope with connected mirror array. If the means 7 contain a telescope, then X denotes an intermediate image plane, while X′ is a (supplemental) pupil plane.

After passing through the manipulation means 7, preferably all partial beams Bᵢ in a fixed angle relation to each other meet in a common pupil (not in the case of the telescope with connected minor array), in which a first deflection mirror of the deflection unit 5 is arranged, which scans the separate illumination spots imaged by the microscope objective 8 over the specimen. The common pupil (preferably for a series of spots as a spot pattern) can lie on a surface of a deflection mirror or, if two deflection minors are present, between the two deflection mirrors. In the case M=1 (series of spots), the common pupil preferably lies on the deflection minor which deflects the partial beams in the lengthwise direction of the series of spots. In particular, when two deflection minors are present, one deflection mirror can be imaged on the other.

Fluorescent light generated in the specimen is collimated by the microscope objective, in particular the objective 8, into separate partial beams with a fixed angle relation to each other and steered by the deflection unit 5 onto stationary partial beams Dᵢ. After this, the manipulation means 7 running backwards from the specimen light performs an inverse manipulation, so that after transmission through the main beam splitter 4 an invariant imaging of the specimen light on the array of confocal detectors 10 is possible through an appropriately designed optics 6.

### LIST OF REFERENCE NUMBERS

1. Scanning microscope
2. Multibeam light source
3. Pupil generating optics
4. Main beam splitter
5. Deflection unit
6. Detection optics
7. Means of manipulation of a spatial position of the partial beams
8. Microscope objective
9. Confocal detection diaphragms
10. Detector
L Laser
S Scanning module
M Microscope module
F Detection module
B Illumination beam path
D Detection beam path
C Joint beam path
X Supplemental pupil plane (intermediate image plane in the case of a telescope)
X′ Supplemental pupil plane in the case of a telescope vP Specimen plane

1. A confocal scanning electron microscope, comprising:
an illumination beam path with a multibeam light source for generating a respective partial beam for different spots, a detection beam path with confocal detectors, a beam splitter, which couples the illumination beam path and the detection beam path into a joint beam path, and an adjustable deflection unit and a microscope objective in the joint beam path for focusing the partial beams of the multibeam light source in a specimen plane, characterized in that means for manipulation of a spatial position of the partial beams are arranged in the joint beam path between the main beam splitter and the deflection unit.

2. The confocal scanning electron microscope according to claim 1, wherein the means for manipulation of a spatial position of the partial beams determine the relative position of the partial beams to each other, in particular, laterally to the optical axis of the partial beams, while the relative distances of the resulting light spots from each other in the same image plane remain intact.

3. The confocal scanning electron microscope according to claim 1, wherein the means for manipulation of a spatial position of the partial beams comprise an adjustable image field rotating element.

4. The confocal scanning electron microscope according to claim 3, wherein the image field rotating element is a pivoting Abbe-Konig prism or a Dove prism.

5. The confocal scanning electron microscope according to claim 3, comprising a control unit, which controls the deflection unit in dependence on an adjustment of the image field rotating element.

6. The confocal scanning electron microscope according to claim 1, wherein the means for manipulation of the spatial position of the partial beams comprise a variable zoom optics.

7. The confocal scanning electron microscope according to claim 1, wherein the means for manipulation of the spatial position of the partial beams comprise a telescope optics for generating an intermediate image and an array of reflection elements which are continuously adjustable in their direction of reflection.

8. The confocal scanning electron microscope according to claim 7, wherein a principal plane of an exit optics of the telescope optics lies outside the telescope, in particular, in the array of reflection elements, especially such that all telescopically imaged partial beams are imaged on different reflection elements.

9. The confocal scanning electron microscope according to claim 1, wherein the means for manipulation of the spatial position of the partial beams determine the relative position of the partial beams to a predetermined point on an axial beam, especially on an axial beam in the means.

10. The confocal scanning electron microscope according to claim 1, wherein the means for manipulation of the spatial position of the partial beams comprise a movably mounted, transparent, plane parallel plate.

11. A confocal scanning electron microscope, comprising: an illumination beam path with a multibeam light source and a series connected collimation optics for generating a respective partial beam for different spots, a detection beam path with confocal detectors, a beam splitter, which couples the illumination beam path and the detection beam path into a joint beam path, and an adjustable deflection unit and a microscope objective in the joint beam path for focusing the partial beams of the multibeam light source in a specimen plane, characterized in that the joint beam path between the main beam splitter and the deflection unit comprises means for manipulation of a phase position of the partial beams relative to each other.

12. The confocal scanning electron microscope according to claim 11, wherein means for manipulation of a phase position of the partial beams comprise a spatial light modulator.

13. The confocal scanning electron microscope according to claim 11, wherein means for manipulation of a phase position of the partial beams comprise a membrane mirror.

14. The confocal scanning electron microscope according to claim 11, wherein means for manipulation are arranged in a pupil plane.

15. The confocal scanning electron microscope according to claim 11, wherein the joint beam path comprises optics for generating the pupil plane.

16. The confocal scanning electron microscope according to claim 11, wherein the microscope objective images several spots from a real or virtual image plane of the multibeam light source in the specimen plane.
